(19) United States
(12) Patent Application Publication
(10) Pub. No.: US 2013/0249025 A1
(43) Pub. Date: Sep. 26, 2013

(54) MAGNETORESISTIVE ELEMENT AND MAGNETORESISTIVE RANDOM ACCESS MEMORY WITH THE SAME

(71) Applicants: Katsuaki NATORI, Kanagawa-ken (JP); Toshihiko Nagase, Tokyo (JP); Eiji Kitagawa, Kanagawa-ken (JP); Tadashi Kai, Tokyo (JP)

(72) Inventors: Katsuaki NATORI, Kanagawa-ken (JP); Toshihiko Nagase, Tokyo (JP); Eiji Kitagawa, Kanagawa-ken (JP); Tadashi Kai, Tokyo (JP)

(73) Assignee: Kabushiki Kaisha Toshiba, Tokyo (JP)

(21) Appl. No.: 13/607,700

(22) Filed: Sep. 8, 2012

(30) Foreign Application Priority Data
Mar. 21, 2012 (JP) P2012-064376

(51) Int. Cl. H01L 43/02; H01L 43/12

(52) U.S. Cl. CPC H01L 43/02; H01L 43/12
USPC 257/421; 438/3

(57) ABSTRACT

According to one embodiment, a magnetoresistive element includes a bottom electrode, a first magnetic layer with an magnetic axis substantially perpendicular to a film plane thereof, a first interface layer, an MgO insulating layer, a second interface layer, a second magnetic layer with an magnetic axis nearly perpendicular to a film plane thereof, and a top electrode. The magnetoresistive element has a diffusion barrier layer between the first magnetic layer and the first interface layer when the first magnetic layer contains Pt or Pd, and a diffusion barrier layer between the second magnetic layer and the second interface layer when the second magnetic layer contains Pt or Pd. The diffusion barrier layer is an Hf film of thickness 0.6 nm to 0.8 nm.

### CROSS-REFERENCE TO RELATED APPLICATION

This application is based upon and claims the benefit of priority from Japanese Patent Application No. 2012-064376, filed Mar. 21, 2012, the entire contents of which are incorporated herein by reference.

### FIELD

Embodiments described herein relate generally to a magnetoresistive element and a magnetoresistive random access memory provided with the same.

### BACKGROUND

In recent years, magnetoresistive random access memory (MRAM) utilizing a tunneling magnetoresistive (TMR) material has been proposed as a nonvolatile semiconductor memory. MRAM is a nonvolatile semiconductor memory possessing distinguishing features suitable for high-speed writing and reading, low power consumption, large capacity, and applications to working memory. The MRAM has a magnetic tunnel junction (MTJ) which is magnetoresistive whose resistance changes depending on the magnetizing direction of the magnetizing film in the MTJ element.

MRAM systems have traditionally used the magnetic field induced by an electric current flowing through wires close to the MTJ element (magnetic field writing method) to invert the magnetizing direction of the free magnetizing layer in the MTJ element. This method, however, makes MRAM integration difficult because the wires generating the magnetic field have to be directly adjacent to the MTJ element. This has prompted the study of a different technique, the spin injection writing method, in which a spin polarizing current is used to reverse the magnetization of the element. This method inverts the magnetizing direction of the magnetization free layer in the MTJ element by passing a spin-polarized current (inversion current) through it. In the spin injection method, integration of MRAM is easy since each memory cell is essentially a cell selection transistor paired with an MTJ element, similar to DRAM (Dynamic Random Access Memory).

An MTJ element that uses the spin polarized current includes a free magnetization layer including a magnetizing film whose magnetizing direction is flipped by the spin-polarized current, a fixed magnetization layer including a magnetized directionally fixed film, and a tunnel barrier layer sandwiched between these two layers. In addition, there are interface layers to maintain a high MR ratio (magnetoresistance ratio) between the free and fixed magnetization layers and the tunnel barrier layer.

Broadly speaking, there are two kinds of MTJ elements. The first type include MTJ elements with an in-plane magnetizing mode, where the in-plane magnetizing film has an magnetizing axis substantially parallel to a film plane thereof. The second type of MTJ element employs a vertical magnetizing mode with a magnetizing film having its magnetizing axis almost perpendicular to a film plane thereof.

### DESCRIPTION OF THE DRAWINGS

FIG. 1 shows a cross section of an MTJ element of a first embodiment.

FIG. 2 shows a cross section showing how an MRAM of the first embodiment is fabricated.

FIG. 3 shows a cross section showing how the MRAM of the first embodiment is fabricated.

FIG. 4 shows a cross section showing how the MRAM of the first embodiment is fabricated.

FIG. 5 shows a cross section showing how the MRAM of the first embodiment is fabricated.

FIG. 6 is a diagram illustrating first and second embodiments.

FIG. 7 is a diagram for illustrating first and second embodiments.

FIG. 8 is a cross section of an MTJ element of a second embodiment.

### DETAILED DESCRIPTION

According to one embodiment, the device is explained by referring to the drawings attached. However, parts common to the different figures are indicated using the same symbols so as to avoid duplicate explanation. The figures are schematic diagrams used for explaining the embodiments and the precise shape, size, ratio, etc. may differ from those in the actual device. However, they can be modified based on the explanation and technology described below.

According to embodiments, a switchable magnetoresistive element useful in magnetic tunnel junction (MTJ) is provided. As will be explained in more detail herein, the magnetoresistive element commonly comprises, in order, a first, fixed magnetic layer, a diffusion barrier layer disposed over the first magnetic layer, an interlayer (e.g., highly orientated magnetic layer) which provides at least one switchable magnetic domain therein, a second diffusion barrier layer and a second magnetic layer.

The first and second magnetic layers may contain precious metals, such as platinum or palladium. It has been found that platinum and palladium deteriorate the stability of the switchable magnetic domains in the interface layer. According to present embodiments, the inventors have discovered that using the element hafnium for the diffusion barrier layer ameliorates the affect of platinum or palladium on the stability of the magnetic domains. Accordingly, the reliability of the MTJ may be improved using hafnium in the diffusion barriers.

In particular, the invention is useful to enable a thin diffusion barrier layer, which unlike thicker diffusion barrier layers, does not attenuate the magnetic coupling between the first magnetic layer and the switchable interface layer. Whereas a thick diffusion barrier layer ameliorates the detrimental effect the presence of platinum or palladium has in the magnetic layer, it also has the detrimental effect of attenuating the magnetic coupling between the first magnetic layer and the switchable interface layer. Thus, a thin barrier layer having a thickness on the order of 0.6-0.8 nm is enabled by incorporating hafnium therein, when the magnetic layer includes platinum or palladium, and the attenuation of the magnetic coupling caused by the thicker barrier layer is substantially reduced.

According to an embodiment, there is provided a magnetoresistive element capable of preventing diffusion of precious metals from the fixed and free magnetization layers into the interface layer during heat treatment, without hindering magnetization bonding between the free and fixed magnetization layers and the interface layer.

In general, according to one embodiment, a magnetoresistive element possesses a bottom electrode, a first magnetic layer with an easy axis of magnetization nearly perpendicular to a film plane thereof, a first interface layer formed on top of the first magnetic layer, an MgO insulating layer on the first interface, a second interface layer on the insulating layer, a second magnetic layer formed on top the second interface layer with an easy axis of magnetization nearly perpendicular to a film plane thereof, and a top electrode on the second magnetic layer. The MTJ cell has a diffusion barrier layer between the first magnetic layer and the first interface layer when the first magnetic layer contains Pt, and a diffusion barrier layer between the second magnetic layer and the second interface layer when the second magnetic layer contains Pt. The diffusion barrier layer contains Hf and has a film thickness of 0.6 nm to 0.8 nm.

### Embodiment 1

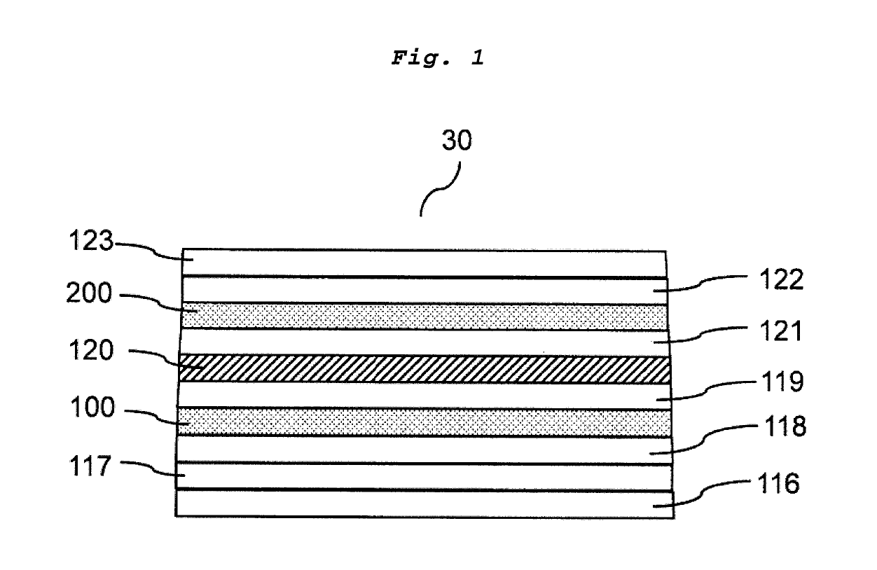

An embodiment is explained in FIG. 1 which shows a cross section of an MRAM 1. In what follows we will describe an MTJ element (Magnetic Tunnel Junction element) 30 which employs a vertical magnetizing film. That is, the vertical magnetizing film is a magnetizing film having a magnetizing direction (easy axis direction of magnetization) substantially perpendicular to a film plane of the magnetizing film in this disclosure.

As shown in FIG. 1, the MTJ element 30 in the present embodiment has a bottom electrode 116 on which a crystal orientation controlling film 117, a fixed magnetization layer (first magnetic layer) 118, a diffusion barrier layer 100, a highly oriented magnetic layer (first interface layer) 119, a tunnel barrier layer (insulating layer) 120, a highly oriented magnetic layer (second interface layer) 121, a diffusion barrier layer 200, a free magnetization layer (second magnetic layer) 122, and a top electrode 123 are sequentially laminated.

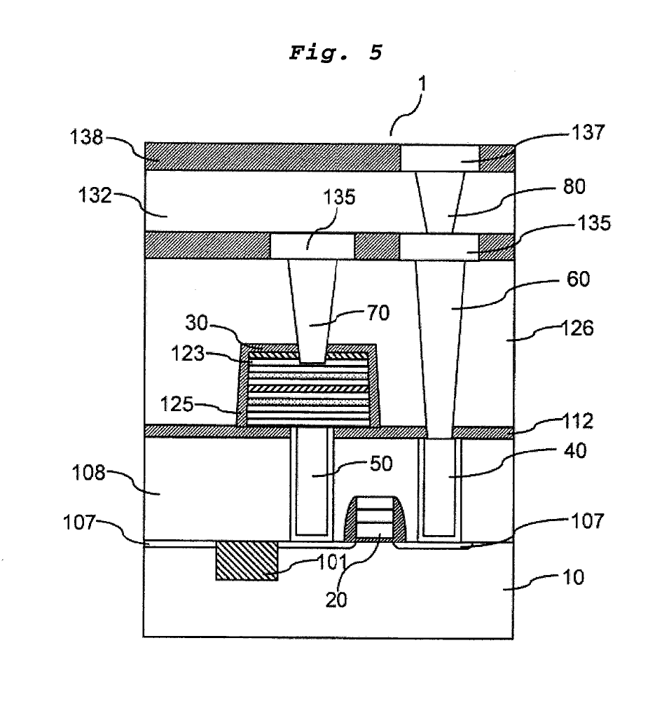

As explained in detail below, the MTJ element 30 in this embodiment has diffusion barrier layers 100, 200 that block diffusion of precious metals from the fixed and free magnetization layers 118 and 122 into the highly oriented magnetic layers 119, 121 when the MRAM 1 (e.g., see FIG. 5) is heat treated during fabrication. The diffusion barrier layers 100, 200 also inhibit crystal orientation in the highly oriented magnetic layer 119 from being influenced by the crystal orientation of the fixed magnetization layer 118 when the MTJ element 30 is fabricated. As a result, the highly oriented magnetic layer 119 can be formed with a good crystal structure. In addition, the free magnetization layer 122 can be formed with a good crystal structure because the highly oriented magnetic layer 121 cannot influence the crystal orientation of the free magnetization layer 122 due to the existence of the diffusion barrier layer 200. Specifically, the highly oriented magnetic layer 119 and the fixed magnetization layer 118 differ in their crystal structure or direction, as do the free magnetization layer 122 and the highly oriented magnetic layer 121. Because controlling the crystal orientation as well as blocking the diffusion of precious metal is important, a high MR ratio can thus be achieved in the MTJ element 30 in this embodiment. The details of the diffusion barrier layers 100, 200 will be explained later.

In order to fix the magnetizing direction of the fixed magnetization layer 118 in one direction, an anti-ferromagnetic layer (not shown in the figure) may be provided adjacent to the fixed magnetization layer 118. The anti-ferromagnetic layer can be sandwiched between the fixed magnetization layer 118 and the diffusion barrier layer 100 or between the diffusion barrier layer 100 and the highly oriented magnetic layer 119. The anti-ferromagnetic layer may be formed of FeMn, NiMn, PtMn, PtPdMn, RuMn, OsMn, IrMn, CrPtMn, etc., which are manganese alloys (Mn) with iron (Fe), nickel (Ni), platinum (Pt), palladium (Pd), ruthenium (Ru), osmium (Os), iridium (Ir), etc.

The bottom electrode 116 can, for instance, be a tantalum (Ta) film of thickness 5 nm.

The orientation controlling film 117 can, for instance, be a 5 nm thick Pt film with (001) crystal orientation. The film 117 need not be Pt′. Ir, Ru and laminated films thereof, for example, can also be used for the orientation controlling film 117.

The fixed magnetization layer 118 is a vertical magnetizing film containing precious metals such as Pt, cobalt (Co), etc. The fixed magnetizing layer 118 can be a 10 nm thick Fe₅₀Pt₅₀-containing magnetizing film. In addition, the fixed magnetization layer 118 need not be a Fe₅₀Pt₅₀ vertical magnetizing film and one could also use Co₅₀Pt₅₀, Co₃₀Fe₂₀Pt₅₀, or (Fe₅₀Pt₅₀)₈₈— (SiO₂)₁₂, which has a partitioned structure obtained by interspersing the film with silicon oxide (SiO₂) or magnesium oxide (MgO) film. For ease of control and fabrication, according to an embodiment, the fixed magnetization layer 118 is a vertical magnetizing film with a high magnetization and to contain precious metals such as Pt, Co, etc.

Diffusion barrier layers 100, 200 are hafnium (Hf) films of thickness 0.6 nm to 0.8 nm. They block the diffusion of the precious metals from the fixed and free magnetization layers 118 and 122 into the highly oriented magnetizing layers 119, 121 during the heat treatment used to fabricate the MRAM 1. Further details are explained later.

The highly oriented magnetic layers 119, 121 should ideally be vertically magnetizing film a having a high polarization rate such as Co₅₀Fe₅₀ film, etc. In order to obtain a high MR ratio and low inversion current, and the film thickness should range from 1 nm to 1.5 nm to make the magnetizing direction substantially perpendicular to the film plane.

The tunnel barrier layer 120 can be a MgO film of thickness 1.0 nm. The tunnel barrier layer 120 need not be a MgO film, other films can be used. the MR ratio of MTJ element 30 may degrade if the precious metals in fixed and free magnetization layers 118 and 122 diffuse into the tunnel barrier layer 120. However, due to the highly oriented magnetic layers 119, 121 between the tunnel barrier layer 120 and the fixed or free magnetization layers 118 or 122, the distance between the tunnel barrier layer 120 and the fixed or free magnetization layers 118 or 122 is increased. Accordingly, the diffusion barrier layers 100, 200 of the MTJ element 30 in this embodiment inhibit the diffusion of the precious metals from the fixed and free magnetization layers 118 and 122 into the tunnel barrier layer 120, thereby preventing degradation of the MR ratio.

The free magnetization layer 122 is a vertical magnetizing film containing a precious metal such as Pt, Co, etc. and, for instance, a laminated film [Co/Pt] 5 obtained by layering 5 pairs of 0.4 nm-thick Co film and 0.8 nm-thick Pt film. The free magnetization layer 122 need not be a laminated film, an artificial Co/Pd lattice can be used instead. In addition, the number of pairs of the laminated film can be changed between 1 and 10 depending on the desired characteristics of the MTJ element 30. Alloys of Co and Pt can also be used for the free magnetization layer 122. For ease of control and fabrication, the free magnetization layer 122 should ideally be a vertical magnetizing film with a high magnetization containing precious metals such as Pt, Co, etc.

The top electrode 123 can, for instance, be a Ta film of thickness 10 nm.

Furthermore, the layered structure of the MTJ element 30 in this embodiment is not limited to that shown in FIG. 1, various shapes can be used. Thus, additional layers can be added, or existing layers can be removed. The MTJ element 30 in this embodiment need not have both diffusion barriers layers 100, 200, it is possible to have just one diffusion barrier layer and still block diffusion of precious metals from the fixed and free magnetization layers 118 and 122 during heat treatment.

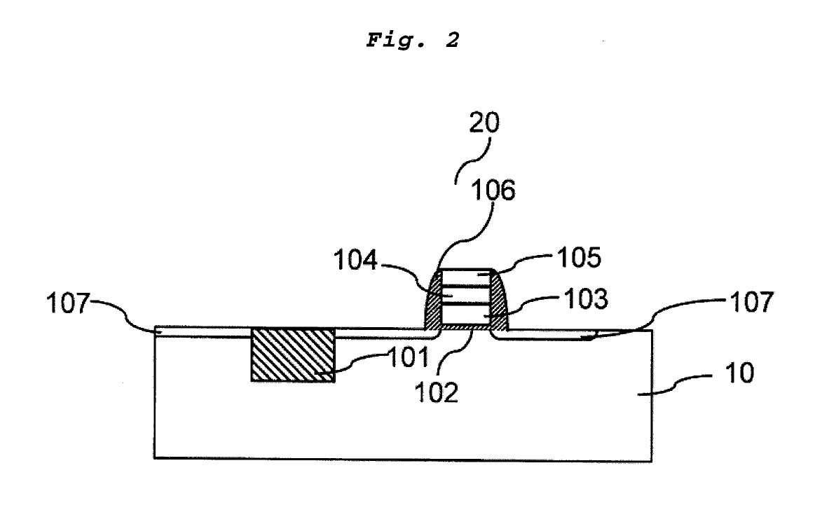

In some cases the layered structure of the MTJ element 30 in this embodiment may be such that the interface between the layers is not clear. For instance, the fixed magnetization layer 118, diffusion barrier layer 100 and highly oriented magnetic layer 119 may be a monolithic layer. Similarly, the highly oriented magnetic layer 121, diffusion barrier layer 200 and free magnetization free 122 may sometimes have the form of a monolithic layer. In these cases, when a 1 nm-thick MgO film is used as the tunnel barrier layer 120 in the MTJ element 30, Hf atoms in 100 or 200 are 1.886 to 2.500 times to the Mg atoms. A method for fabricating the MRAM 1 having the MTJ element 30 shown in FIG. 1 is explained with reference to FIG. 2 to FIG. 5, which show cross-sections of the MRAM 1. However, the present disclosure is not limited to the method of MRAM 1 fabrication described below.

First, referring to FIG. 2, an isolation groove is formed next to a transistor active region by the usual method in the surface of the p-type semiconductor substrate 10, such as reactive ion etch of silicon. An insulating SiO₂ film, etc. is deposited in the groove to form a shallow trench (STI (Shallow Trench Isolation)) 101.

A transistor for a switching operation is fabricated. First, an oxide film 102 of thickness of about 6 nm is formed on the semiconductor substrate 10 by thermal oxidation, and an arsenic-doped n⁺ type polycrystalline silicon film 103 is deposited on the oxide film 102, followed by deposition of tungsten silicide (WSiₓ) film 104 and a nitride film 105. Using photolithographic and RIE (Reactive Ion Etching) techniques, the polycrystalline silicon film 103, tungsten silicide film 104 and nitride film 105 are then patterned to form a gate electrode 20 in the multilayer structure. A nitride film 106 is deposited for the side wall of the gate electrode 20. A spacer including the nitride film 106 is formed on the side of the gate electrode 20 by RIE to form side walls. A source-drain region 107 is formed, next to the gate electrode 20, in the semiconductor substrate 10 by ion injection and heat treatment. The result is shown in FIG. 2.

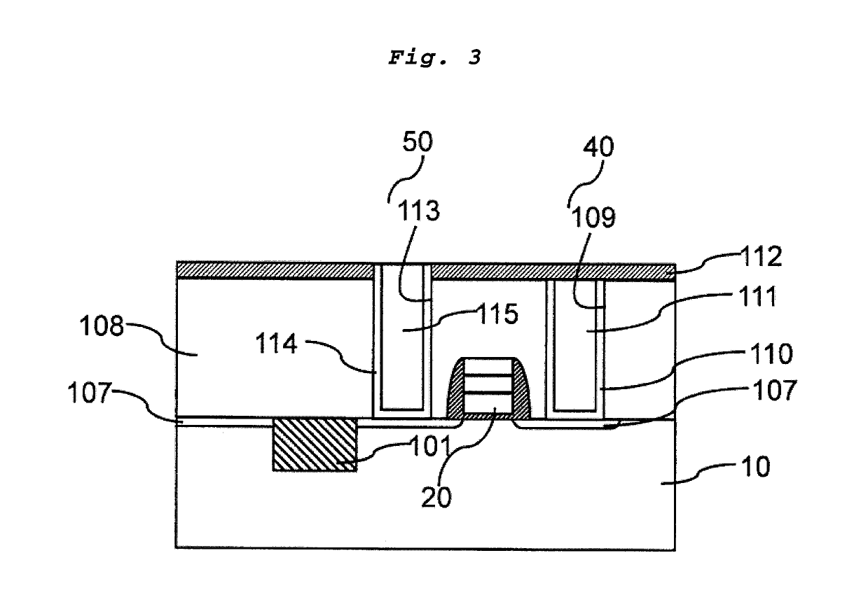

Then, referring to FIG. 3, a silicon oxide film 108 is then deposited by a CVD (Chemical Vapor Deposition) on the transistor in the semiconductor substrate 10, and the top of the silicon oxide film 108 is polished flat by CMP (Chemical Mechanical Polishing). In addition, a contact hole 109 connected to one side of the source-drain region 107 is formed using traditional lithographic and RIE techniques.

Then, a thin titanium film is deposited on the inside of the contact hole 109 by sputtering or CVD and heat treated in a forming gas containing N, such as NH₃, to form a titanium nitride film (TiN) 110 coating the inside of the contact hole 109. A tungsten film 111 is deposited on the inside of the contact hole 109, already coated with the TiN film 110, by CVD using a tungsten hexa-fluoride gas (WF₆), and a portion of the tungsten film 111 sticking out from the contact hole 109 is removed by CMP to form a contact plug 40.

A silicon nitride film 112 is deposited over the oxide film 108 by CVD and a contact hole 113 connecting with the other source-drain region 107 is formed by using lithographic and RIE techniques as explained previously. A titanium nitride film 114 coating the inside of the contact hole 113 is formed as described before, and a tungsten film 115 is deposited on the inside of the contact hole 113 coated with the titanium nitride film 114, and a portion of the tungsten film 115 sticking out from the contact hole 113 is then removed to form a contact plug 50 connected to MTJ element 30. The resulting structure is shown in FIG. 3.

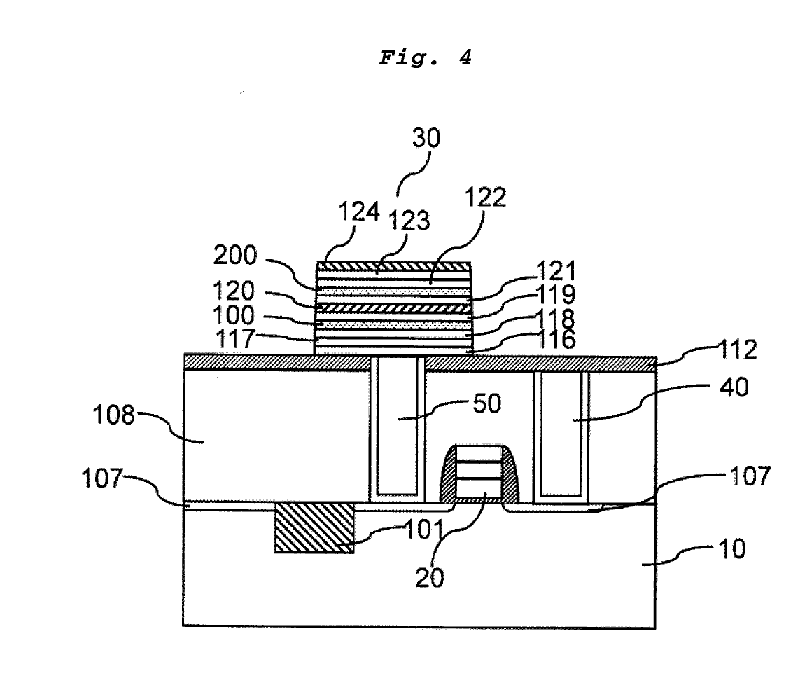

Referring again to FIG. 1, a film stack for forming an MTJ element as shown in FIG. 4 begins with sputtering a Ta film of thickness 5 nm, for example, to form a bottom electrode 116 of the MTJ element 30.

A Pt film of thickness 5 nm, for example, is sputtered onto the bottom electrode 116 to form a crystal orientation controlling film 117 of the MTJ element 30. As explained previously, the crystals in the orientation controlling film 117 have the (001) orientation.

A vertical magnetizing film containing Fe₅₀Pt₅₀ of thickness 10 nm, for example, is then sputtered on the orientation controlling film 117 to form the fixed magnetization layer 118.

An Hf film of thickness 0.6 nm to 0.8 nm serving as the diffusion barrier layer 100 is then deposited on the fixed magnetization layer 118. More specifically, an Hf barrier film 100 of thickness 0.8 nm, for example, can be formed in 14 seconds by sputtering in Ar flowing at 60 sccm at a sputtering power of 200 W.

Next, a first Co₄₀Fe₄₀B₂₀ film of thickness 1 nm to 1.5 nm, for example, is sputtered on the diffusion barrier layer 100 to form a first highly oriented magnetizing layer 119.

Thereafter, a MgO film of thickness 1.0 nm, for example, serving as the tunnel barrier 120 is sputtered on the highly oriented magnetizing layer 119.

A second CO₄₀Fe₄₀B₂₀ film of thickness 1 nm to 1.5 nm, for instance, is sputtered on the tunnel barrier layer 120 to form a second highly oriented magnetizing layer 121.

An Hf film of 0.6 to 0.8 nm thick is then deposited on the highly oriented magnetizing layer 121 to form the diffusion barrier layer 200. Since the Hf diffusion barrier 200 is formed in the same way as the diffusion barrier layer 100, further details are omitted.

Next, the free magnetization layer 122 including a vertical magnetizing layer sputtered on the diffusion barrier layer 200. As explained previously, the free magnetization layer 122 is a laminated film [Co/Pt] 5 obtained by 5 cycles of Co film having thickness of 0.4 nm and Pt film of thickness 0.8 as one cycle, for example.

A Ta film of thickness 10 nm, for example, is then sputtered to form the top electrode 123.

Crystallization annealing of the MgO film tunnel barrier 120 is then performed at 360° C. in vacuum for 1 hour. Although the annealing temperature does not have to reach 360° C., to get MgO films with a good crystal structure it should be at least 350° C. After annealing, both the MgO film tunnel barrier layer 120 and the Co₄₀Fe₄₀B₂₀ film in the highly oriented magnetic layers 119, 121 are crystallized. At that time, the boron (B) in the highly oriented magnetic layers 119, 121 then diffused out so that the highly orientated magnetic layers 119, 121 become Co₅₀Fe₅₀ films.

An silicon oxide film 124 useful as a mask and photoresist (not shown) is deposited on the electrode 123. The oxide film 124 is patterned by photolithographic and RIE techniques. The photoresist is removed, and the film stack is etched by RIE to form the top electrode 123, the free magnetization layer 122, the diffusion barrier layer 200, the highly oriented magnetic layer 121, the tunnel barrier layer 120, the highly oriented magnetic layer 119, the diffusion barrier layer 100, the fixed magnetization layer 118, the orientation control film 117, and the bottom electrode 16, in a single region confined over the contact plug 50 and adjacent to the nitride layer 112. The resulting MTJ element 30 is formed on a contact plug 50 to give the structure shown in FIG. 4.

Now, referring to FIG. 5, a protective silicon nitride film 125 of thickness 5 nm, for example, is then formed by CVP on the top and sides of the MTJ element 30.

In addition, an interlayer dielectric 126 including an SiO₂ film covering the MTJ element 30 and silicon nitride film 112 is formed by CVD. In more detail, the interlayer dielectric 126 including the SiO₂ film is formed using TEOS (tetraethoxysilane) and oxygen by RF plasma processing at a substrate temperature of 350° C.

Two contact holes are formed simultaneously in the interlayer dielectric 126 to form a contact plug 70 connected to the top electrode 123 of the MTJ element 30 and a contact plug 60 connected to the contact plug 40.

The TiN barrier layer to cover the inside of the contact holes (not shown) is then formed by CVD from titanium tetrachloride (TiCl₄) and ammonia (NH₃) at 350° C. The tungsten film (not shown) is deposited by CVD from tungsten hexafluoride (WF₆) gas to fill the inside of the contact holes already coated with the barrier layer, and a portion of tungsten film projecting from the holes is removed by CMP to form the contact plugs 60, 70.

An upper wiring 135 is formed on the contact plugs 60, 70 by the usual method.

An interlayer dielectric 132 is further deposited on the interlayer dielectric 126 and a contact hole to contact the upper wiring 135 is formed by lithographic and RIE techniques. An aluminum (Al) film is applied to the contact hole and polished flat by CMP to form a contact plug 80. An interlayer dielectric 138 is then formed on the interlayer dielectric 132 and a wiring groove to hold the wiring is made by lithography and RIE in the interlayer dielectric 138 on the contact plug. The Al film is then filled in the wiring groove and polished flat by CMP to form a second upper wiring 137. The resulting MRAM 1 is shown in FIG. 5.

In the present embodiment, diffusion of precious metals in the fixed and free magnetization layers 118 and 122 into the highly oriented magnetic layers 119, 121 during heat treatment when the MRAM 1 is being fabricated can be prevented, due to the 0.6 to 0.8 nm thickness Hf diffusion barrier layers 100, 200 in the MTJ element 30. This will be explained in detail below.

Because the MTJ elements previously used lack the hafnium based diffusion barrier layers 100, 200 included in the present embodiment, during heat treatment at or above 350° C., the precious metals in the fixed and free magnetization layers 118 and 122 diffuse into the highly oriented magnetic layers 119, 121 and disrupt the crystal structure, thereby degrading the MR ratio of a MTJ device.

However, the MTJ element 30 in the present embodiment can avoid degradation of MR ratio of MTJ element 30 since it has Hf in the diffusion barrier layers 100, 200 of thickness 0.6 nm to 0.8 nm. In detail, since the Hf film can retain a high residual magnetization, magnetic coupling between the fixed magnetization layer 118 and the highly oriented magnetic layer 119 and between the free magnetization layer 122 and the highly oriented magnetic layer 121 is not hindered. Even during heat treatment, where temperatures of 350° C. and above are applied to the MTJ element 30, the diffusion barrier layers 100, 200 keep the precious metals in the fixed and free magnetization layers 118 and 122 from diffusing into the highly oriented magnetic layers 119, 121, so that the MR ratio of the MTJ element 30 remains good.

However, according to embodiments, the Hf diffusion barrier layers 100, 200 are 0.6 nm to 0.8 nm thick, because then the magnetic coupling between the fixed magnetization layer 118 and the highly oriented magnetic layer 119 and between the free magnetization layer 122 and the highly oriented magnetic layer 121 is not hindered and diffusion of precious metals in the fixed and free magnetization layers 118 and 122 into the highly oriented magnetic layers 119, 121 during heat treatment can be prevented. This film thickness is found experimentally by the present inventors as explained below.

First, sample MTJ elements used in the experiment will be explained. They are obtained by sandwiching a highly oriented magnetic layers laminate of Co₅₀Fe₅₀ film obtained by sandwiching a tunnel barrier layer including a MgO film of thickness 1 nm by a vertical magnetizing layer containing Pt and Co through the diffusion barrier layer, which contained an Hf film of various thicknesses. Each layer in the sample MTJ element is formed in the same manner as in the first embodiment.

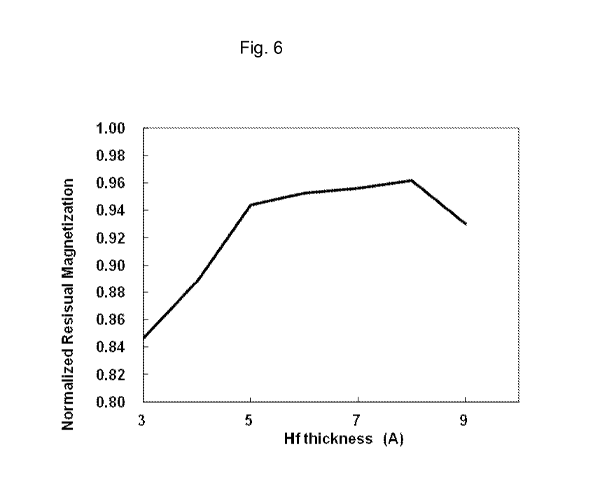

The present inventors measured the residual magnetization of the MTJ samples and the results are shown in FIG. 6. In FIG. 6, the x-axis plots the thickness of the Hf film diffusion barrier layer, and the y-axis shows the magnitude of the residual magnetization relative to the saturated magnetization per unit area. It is clear from FIG. 6 that the MTJ element retains a high residual magnetization when the Hf film diffusion barrier layer thickness is 5 Å (0.5 nm) to 8 Å (0.8 nm).

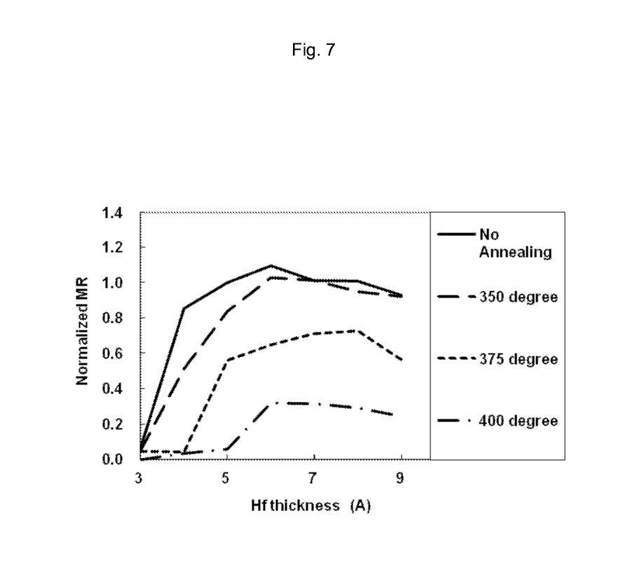

The samples are annealed at various temperatures under vacuum (1×10⁻⁴ Pa) for 1 hour to obtain results shown in FIG. 7. In FIG. 7, the x-axis is the film thickness of the Hf film diffusion barrier layer, and the y-axis shows the MR ratio relative to the MR of an MTJ element having an Hf film of thickness 5 Å which is not annealed. Further, the annealing temperature is shown for four categories: no annealing, 350° C., 375° C., and 400° C. It is clear from FIG. 7 that when annealed at 350° C. or higher, the MR ratio is degraded for MTJ elements having a diffusion barrier layer either without any Hf film or with an Hf film less than 6 Å (0.6 nm) thickness, whereas the MR ratio for an MTJ element with a diffusion barrier layer with an Hf film 6 Å (0.5 nm) to 8 Å (0.8 nm) thickness is hardly degraded.

The above results clearly show that that the Hf film in the diffusion barrier layers 100, 200 should have a thickness between 0.6 nm and 0.8 nm in order to maintain a high residual magnetization without hindering the magnetizing coupling between the fixed magnetization layer 118 and the highly oriented magnetic layer 119 and between the free magnetization layer 122 and the highly oriented magnetic layer 121, and to prevent diffusion of precious metals in the fixed and free magnetization layers 118, 122 into the highly oriented magnetic layers 119, 121.

Thus, since the MTJ element 30 in this embodiment has diffusion barrier layers 100, 200 with an Hf film of thickness between 0.6 nm and 0.8 nm, magnetic coupling between the fixed magnetization layer 118 and the highly oriented magnetic layer 119 and between the free magnetization free layer 122 and the highly oriented magnetic layer 121 is not hindered, and diffusion of precious metals in the fixed and free magnetization layers 118, 122 into the highly oriented magnetic layers 119, 121 can be prevented. In this embodiment, the MR ratio of the MTJ element 30 can be kept high. Furthermore, because diffusion of the precious metals is blocked by the diffusion barrier layers 100, 200, the tunnel barrier layer 120 can be crystallized at high temperature to obtain a good crystal structure so that an MTJ element 30 obtains high MR ratio. According to the experiments of the present inventors, a high MR ratio of 140 is obtained even when an MTJ element 30 whose diffusion barrier layers 100, 200 contain Hf film of thickness of 0.6 nm or higher is annealed in vacuum for 1 hour at 350° C.

Owing to the diffusion barrier layers 100, 200 of the MTJ element 30 in this embodiment, crystal growth in the highly oriented magnetic layer 119 influenced by the crystal structure of the fixed magnetization layer 118 in the MTJ element 30 can be inhibited. Thus, the highly oriented magnetic layer 119 with a good crystal structure can be formed and the same goes for the free magnetization layer 122, because crystal growth in the free magnetization layer 122 influenced by the crystal structure in the highly oriented magnetic layer is inhibited. The MTJ element 30 in this embodiment therefore has a high MR ratio.

### Embodiment 2

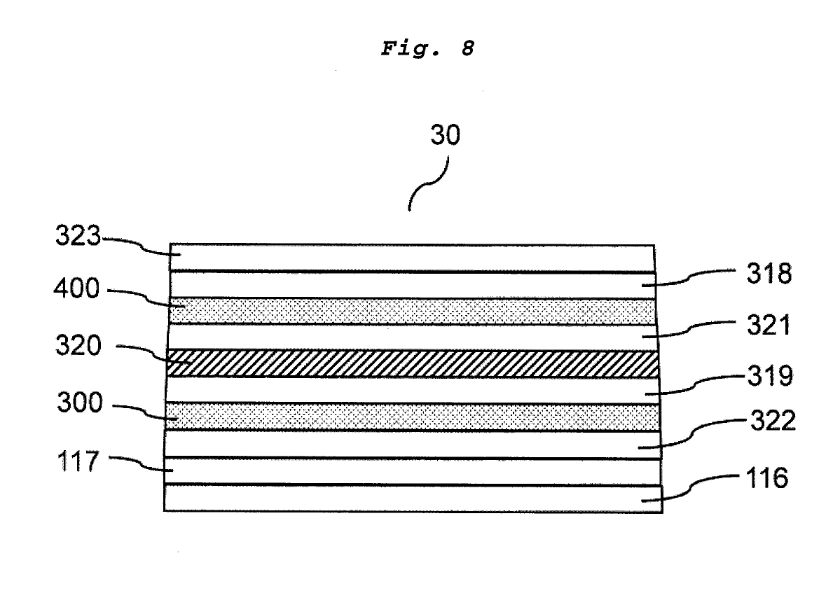

This embodiment differs from the first embodiment in that the lamination order of the layers making up the MTJ element is reversed. The MTJ elements of FIG. 8 have diffusion barrier layers containing Hf film of thickness 0.6 nm to 0.8 nm as in the first embodiment, so that magnetic coupling between the fixed magnetization layer and highly oriented magnetic layer and between the free magnetization layer and highly oriented magnetic layer is not hindered, and precious metals are prevented from diffusing from the fixed and free magnetization layers into the highly oriented magnetic layer.

This embodiment will now be explained for the case of an MTJ element 30 with a vertical magnetizing film. FIG. 8 shows a cross section of the MTJ element. In explaining this embodiment, parts analogous to the corresponding parts in the first embodiment are denoted by the same symbols and their explanation is omitted.

The MTJ element 30 in this embodiment shown in FIG. 8 has a bottom electrode 116 containing a Ta film of thickness 5 nm, for instance, on which the following layers are laminated in order: an orientation controlling film 117, for example, containing a Pt film with crystal orientation (001) and thickness 5 nm, a free magnetization layer (first magnetic layer) 322, a diffusion barrier layer 300 containing Hf film, a highly oriented magnetic layer 319, for example, containing a Co₅₀Fe₅₀ film of thickness 1 nm to 1.5 nm, a tunnel barrier layer 320, for example, containing an MgO film of thickness 1.0 nm, a highly oriented magnetic layer 321 containing a Co₅₀Fe₅₀ film, for example, of thickness 1 nm to 1.5 nm, diffusion barrier layer 400 containing Hf film, a fixed magnetization layer (second magnetic layer) 318 containing an Fe₅₀Pt₅₀ film, for example, of thickness 10 nm, and a top electrode 323, for example, containing a Ta film of thickness 10 nm.

As in the first embodiment, and for the same reasons, it is best for the diffusion barrier layers 300, 400 to contain an Hf film of thickness 0.6 nm to 0.8 nm.

Also, as in the first embodiment, the free magnetization layer 322 contains a vertical magnetizing film which, in more detail, is a lamination [Co/Pt] 5 structure obtained by laminating 5 cycles of Co film of thickness 0.4 nm and a Pt film of thickness 0.8 nm as one cycle, for example.

As in the first embodiment, an anti-ferromagnetic layer (not shown) may be inserted next to the fixed magnetization layer 318 to fix the magnetizing direction of the fixed magnetization layer 318 in one direction. More concretely, the anti-ferromagnetic layer may be sandwiched between the fixed magnetization layer 318 and the diffusion barrier layer 400, or between the diffusion barrier layer 400 and the highly oriented magnetic layer 321. The same film as in the first embodiment can be used as the anti-ferromagnetic layer.

As in the first embodiment the lamination structure of the MTJ element 30 in this embodiment, need not be as shown in FIG. 8, and various shapes can be used. Thus, as in the first embodiment, additional layers may be added or existing layers may be omitted. Again, as in the first embodiment, the MTJ element 30 need not have both the diffusion barrier layers 300, 400, but may have only one.

As in the first embodiment, the interfaces between the layers may sometimes be unclearly defined in the laminated structure of the MTJ element 30. For instance, sometimes the fixed magnetization layer 318, diffusion barrier layer 400, and highly oriented magnetic layer 321 appear as a monolithic layer. The highly oriented magnetic layer 319, diffusion barrier layer 300, and free magnetization layer 322 may also appear as a monolithic layer. In those cases, when a MgO film having thickness 1 nm is used as the tunnel barrier layer 320 of the MTJ element 30, the number of Hf atoms in the monolithic layer (fixed magnetization layer 318 plus diffusion barrier layer 400 plus highly oriented magnetic layer 321) or the monolithic layer (highly oriented magnetic layer 319 plus diffusion barrier layer 300 plus free magnetization free layer 322) ranges from 1.886 to 2.500 times the number of Mg atoms in one MTJ element 30.

Each layer in the MTJ element 30 in this embodiment can be formed in the same manner as in the first embodiment. The fabrication of the MRAM 1 having the MTJ element 30 shown in FIG. 8 is the same as in the first embodiment and its explanation is omitted.

In this embodiment, the MTJ element 30 has diffusion barrier layers 300, 400 containing Hf film of thickness 0.6 nm to 0.8 nm as in the first embodiment, and magnetic coupling between the fixed magnetization layer 318 and the highly oriented magnetic layer 321 and between the free magnetization layer 322 and the highly oriented magnetic layer 319 is not hindered, so precious metals are prevented from diffusing from the fixed and free magnetization layers 318 and 322 into the highly oriented magnetic layers 319, 321. According to this embodiment, the MR ratio of MTJ element 30 can be kept high. Furthermore, since diffusion of precious metals is blocked by the diffusion barrier layers 300, 400, the tunnel barrier layer 320 can be crystallized at high temperature to obtain a tunnel barrier layer 320 with a good crystal structure so that an MTJ element 30 with a good MR ratio is obtained.

As in the first embodiment, the diffusion barrier layers 300, 400 in the MTJ element 30 in this embodiment inhibit crystal growth in the highly oriented magnetic layer 319 influenced by the crystal structure of the free magnetization layer 322 when the MTJ element 30 is being fabricated, and crystal growth in the fixed magnetization layer 318 influenced by the crystal structure in the highly oriented magnetic layer 321 is likewise inhibited.

While certain embodiments have been described, these embodiments have been presented by way of example only, and are not intended to limit the scope of the inventions. Indeed, the novel embodiments described herein may be embodied in a variety of other forms. Furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

1. A magnetoresistive element, comprising:
a fixed magnetic layer;
a highly orientated magnetic layer; and
a diffusion barrier layer disposed between the fixed magnetic layer and the highly orientated magnetic layer, wherein the diffusion barrier layer contains hafnium.

2. The magnetoresistive element of claim 1, wherein the fixed magnetic layer contains at least one of platinum or palladium.

3. The magnetoresistive element of claim 1, wherein the highly orientated magnetic layer provides a switchable magnetic domain.

4. The magnetoresistive element of claim 1, wherein the highly orientated magnetic layer does not provide a switchable magnetic domain.

5. The magnetoresistive element of claim 1, further comprising:
an insulating tunnel barrier layer disposed adjacent to the highly orientated magnetic layer.

6. The magnetoresistive element of claim 5, wherein the insulating tunnel barrier layer contains MgO.

7. The magnetoresistive element of claim 1, wherein the highly orientated magnetic layer contain Co, Fe, or B.

8. The magnetoresistive element of claim 1, further comprising:
an anti-ferromagnetic layer disposed between the fixed magnetic layer and the diffusion barrier layer or disposed between the diffusion barrier layer and the highly orientated magnetic layer.

9. A magnetoresistive element comprising, in order:
a bottom electrode;
a first magnetic layer with a magnetization axis substantially perpendicular to a film plane;
a first diffusion barrier layer containing hafnium;
a first highly oriented magnetic layer;
an insulating tunnel barrier layer containing MgO;
a second highly orientated magnetic layer;
a second diffusion barrier layer containing hafnium;
a second magnetic layer with a magnetization axis substantially perpendicular to the film plane; and
a top electrode.

10. The magnetoresistive element of claim 9, wherein the first and second magnetic layers contain one of platinum or palladium.

11. The magnetoresistive element of claim 9, wherein the first magnetic layer, the first diffusion barrier layer and the first highly oriented magnetic layer form a first single layer and wherein the second diffusion barrier layer and the second highly oriented magnetic layer form a second single layer.

12. The magnetoresistive element of claim 9, wherein the first and second highly orientated magnetic layers contain Co, Fe, or B.

13. A method for forming a magnetoresistive element, comprising
forming a magnetic layer containing a precious metal;
forming a diffusion barrier layer containing hafnium disposed on the first magnetic layer; and
forming an interface layer disposed on the diffusion barrier layer;

14. The method of claim 13, further comprising:
forming an insulating layer containing MgO on the interface layer.

15. The method of claim 14, further comprising:
annealing the magnetoresistive element at a temperature of 350 C or higher in an effort to crystallize the insulating layer.

16. The method of claim 14, further comprising:
forming a second interface layer disposed on the insulating layer;
forming a second diffusion barrier layer containing hafnium disposed on the second interface layer; and
forming a second magnetic layer containing a precious metal, wherein
the first and second magnetic layers are disposed between a bottom and top electrode.

17. The method of claim 16, wherein the precious metal is one of platinum or palladium.

18. The method of claim 16, wherein the first and second diffusion barrier layers of hafnium are of thickness 0.6 to 0.8 nm.

19. The method of claim 13, further comprising:
disposing an anti-ferromagnetic layer, wherein the anti-ferromagnetic layer is disposed between the magnetic layer and the diffusion barrier layer or disposed between the diffusion barrier layer and the magnetic layer, and wherein the anti-ferromagnetic layer fixes the magnetizing direction of the magnetic layer.
